(19) United States
(12) Patent Application Publication
(10) Pub. No.: US 2026/0371965 A1
(43) Pub. Date: Nov. 19, 2026

(54) OXYGEN-FREE ETCHING OF NON-VOLATILE METALS

(71) Applicant: Tokyo Electron Limited, Tokyo (JP)

(72) Inventors: Stephanie Oyola-Reynoso, Albany, NY (US); Ivo Otto, IV, Albany, NY (US); Qi Wang, Albany, NY (US); Aelan Mosden, Albany, NY (US)

(21) Appl. No.: 19/749,876

(22) Filed: Jul. 22, 2026

Related U.S. Application Data
(62) Division of application No. 17/826,236, filed on May 27, 2022.

(51) Int. Cl. H10P 50/26; H10P 50/00; H10W 20/00

(52) U.S. Cl. CPC H10P 50/269; H10P 50/71; H10W 20/056; H10W 20/063

(57) ABSTRACT

A method of processing a substrate that includes: loading the substrate in a processing chamber, the substrate including a non-volatile metal layer, an oxide layer, and a dielectric layer, the oxide layer including an oxide of the non-volatile metal, a surface of the substrate including the oxide layer and the dielectric layer; performing a pretreatment by exposing the substrate to a treatment gas to remove the oxide layer and expose the non-volatile metal layer; performing a non-plasma oxygen-free etch process selective to the dielectric layer by: exposing the substrate to chlorine (Cl₂) in the processing chamber, the Cl₂ reacting with the non-volatile metal to form an intermediate; and exposing the substrate to a ligand-exchange agent in the processing chamber, the ligand-exchange agent reacting with the intermediate to form volatile products, removing the non-volatile metal from the surface of the substrate.

### CROSS-REFERENCE TO RELATED APPLICATIONS

This application is a divisional application and claims the benefit of U.S. Patent Application No. 17/826,236, filed on May 27, 2022, which application is hereby incorporated herein by reference in its entirety.

### TECHNICAL FIELD

The present invention relates generally to a method of processing a substrate, and, in particular embodiments, to oxygen-free etching of non-volatile metals.

### BACKGROUND

Generally, semiconductor devices used in electronics, such as mobile phones, digital cameras, and computers, are fabricated by sequentially depositing and patterning layers of dielectric, conductive, and semiconductor materials over a semiconductor substrate, using photolithography and etching to form structures that function as circuit components (e.g., transistors, resistors, and capacitors) and as interconnect elements (e.g., conductive lines, contacts and vias). Driven by a demand for low-cost electronics, the semiconductor industry has repeatedly reduced the minimum feature sizes in semiconductor devices to a few nanometers with innovations in lithography (e.g., immersion lithography and multiple patterning) to increase the packing density of components, thereby reducing the cost of integrated circuits (ICs). Further increase in density and reduction in cost is achieved using three-dimensional (3D) structures (e.g., the fin field-effect transistors (FinFET)) and, in some instances, stacking electronic components such as memory storage elements (e.g., the ferroelectric capacitor, the magnetic tunnel junction (MTJ), etc.) and precision passive components (e.g., the thin-film resistor (TFR) and the metal-insulator-metal (MIM) capacitor) in layers in between successive interconnect levels.

Plasma processing techniques, such as reactive ion etching (RIE), plasma-enhanced chemical vapor deposition (PECVD), plasma-enhanced atomic layer etch and deposition (PEALE and PEALD), sputter etch, physical vapor deposition (PVD), and cyclic etch-deposition (e.g., the Bosch etch process) have become indispensable in fabricating ICs. The diversity of materials used in IC fabrication such as semiconductors, insulators (including SiO2, Si3N4, high-k gate dielectrics, and low-k dielectrics), magnetic and ferroelectric films, and metals for interconnect and electrodes makes developing plasma processes, and generally fabrication processes, a challenge. Miniaturization to a few nanometers has intensified the challenge. Furthermore, introduction of unconventional materials (e.g., Co and Ru) at feature sizes below 20 nm may raise new issues in developing desired etch and deposition processes compatible with conventional Si IC fabrication.

### SUMMARY

In accordance with an embodiment of the present invention, a method of processing a substrate that includes: forming an etch mask over a ruthenium (Ru) metal layer of a substrate, the etch mask exposing a first portion of the Ru metal layer and covering a second portion of the Ru metal layer; and converting the first portion of the Ru metal layer into a volatile Ru etch product in a processing chamber, the converting including exposing the Ru metal layer of the substrate to a halogen-containing vapor, and to a ligand-exchange agent to form the volatile Ru etch product, where the converting is an oxygen-free process.

In accordance with an embodiment of the present invention, a method of processing a substrate that includes; performing a plasma-free and oxygen-free etch process, the performing including exposing the substrate including ruthenium (Ru) metal to a process gas mixture, the process gas mixture including a first halogen-containing gas and a second halogen-containing gas, the second halogen-containing gas including a halogen different from that of the first halogen-containing gas.

In accordance with an embodiment of the present invention, a method of processing a substrate that includes; loading the substrate in a processing chamber, the substrate including a non-volatile metal layer, an oxide layer, and a dielectric layer, the oxide layer including an oxide of the non-volatile metal, a surface of the substrate including the oxide layer and the dielectric layer; performing a pretreatment by exposing the substrate to a treatment gas to remove the oxide layer and expose the non-volatile metal layer; performing a non-plasma oxygen-free etch process selective to the dielectric layer by: exposing the substrate to chlorine (Cl₂) in the processing chamber, the Cl₂ reacting with the non-volatile metal to form an intermediate; and exposing the substrate to a ligand-exchange agent in the processing chamber, the ligand-exchange agent reacting with the intermediate to form volatile products, removing the non-volatile metal from the surface of the substrate.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1D illustrate cross-sectional views of an example substrate during a fabrication process comprising an oxygen-free etching process in accordance with various embodiments, wherein FIG. 1A illustrates the incoming substrate comprising a ruthenium (Ru) metal layer and a surface Ru oxide layer, FIG. 1B illustrates the substrate after removing the surface Ru oxide layer, FIG. 1C illustrates the substrate after exposing the substrate to a halogen-containing vapor, and FIG. 1D illustrates the substrate after exposing the substrate to a ligand-exchange agent to etch the Ru metal from the substrate;

FIG. 2 illustrates a cross sectional view of an example substrate during a continuous oxygen-free etching process in accordance with alternate embodiments;

FIGS. 3A-3D illustrate cross sectional views of another example substrate comprising direct-etch interconnect lines disposed between a damascene contact level and a dual-damascene interconnect level at various intermediate stages of fabrication including an oxygen-free etching process in accordance with other embodiments, wherein FIG. 3A illustrates the incoming substrate, FIG. 3B illustrates the substrate after the oxygen-free etching process, FIG. 3C illustrates the substrate after removing an etch stop layer, and FIG. 3D illustrates the substrate after forming a intermetal dielectric (IMD) layer;

FIGS. 4A-4C illustrate cross sectional views of yet another example substrate comprising a direct-etch back contact connecting a conductive gate to a metal line at various intermediate stages of fabrication including an oxygen-free etching process in accordance with yet other embodiments, wherein FIG. 4A illustrates the incoming substrate, FIG. 4B illustrates the substrate after the oxygen-free etching process, and FIG. 4C illustrates the substrate after forming an interconnect level; and

FIGS. 5A-5C illustrate example process flow diagrams of an oxygen-free etching process, wherein FIG. 5A illustrates an embodiment and FIG. 5B illustrates an alternate embodiment, and FIG. 5C illustrates yet another embodiment.

### DETAILED DESCRIPTION OF ILLUSTRATIVE EMBODIMENTS

This application relates to methods of etching non-volatile metals, in particular, to a halogen-based, oxygen-free etching process that can etch non-volatile metals such as ruthenium (Ru), which is a new material useful but still challenging to be integrated with conventional semiconductor device fabrication processes. As the scaling of feature sizes of semiconductor devices continues, the interconnect-RC delay of conventional copper (Cu) lines and tungsten (W) contacts may be limiting the speed of digital circuits at small dimensions. New materials are being introduced at the 10 nm nodes and below to replace dense Cu lines and W contacts. Ru metal is a leading candidate for replacing copper and tungsten in these and other applications. Plasma etching of Ru may be possible, for example, utilizing halogen and oxygen chemistry. However, currently available Ru plasma etching processes are not sufficiently selective to other material used in the devices such as low-k dielectric. Therefore, a new etching method may be desired. Embodiments of the present application disclose methods of an oxygen-free etching for non-volatile metals. Further, the methods may also be performed in the absence of plasma. The inventors demonstrated the ability to etch Ru metal without using oxygen or plasma, which may be a substantial advantage over the conventional methods because the oxygen species and plasma conditions often lead to severe damages to low-k dielectric materials.

The methods described in this disclosure may advantageously enable the etching of non-volatile metals such as Ru as part of various back end of line (BEOL) processes, where the etching may be required to be selective to low-k dielectric. In various embodiments, the oxygen-free, non-plasma etching process may be utilized in fabrication of fully self-aligned vias (FSAV), Ru interconnect lines, Ru contacts and vias, and others. While this disclosure primarily describes the etching of Ru, other non-volatile metals may also be etched with the methods. Such metals may be including but not limited to osmium (Os), nickel (Ni), molybdenum (Mo), niobium (Nb), tungsten (W) and hafnium (Hf).

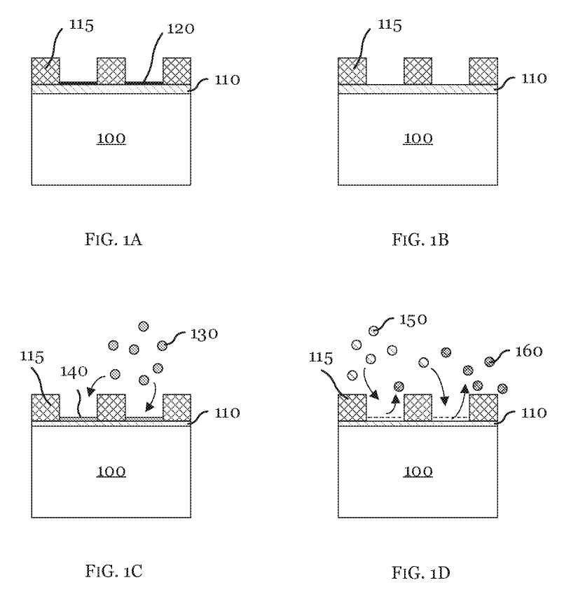

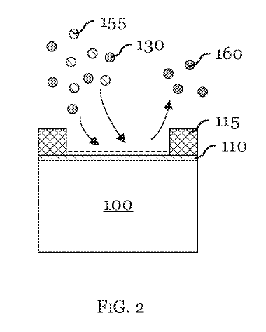

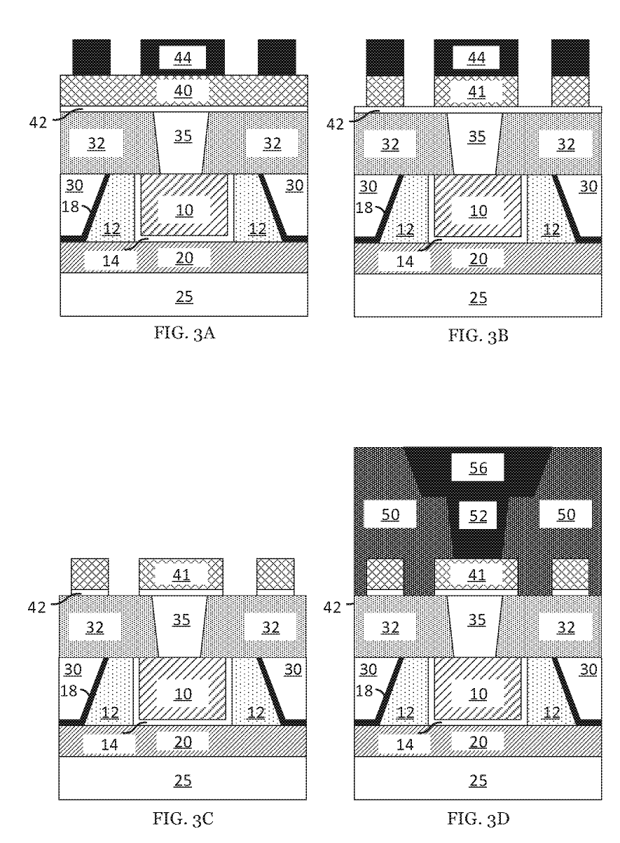

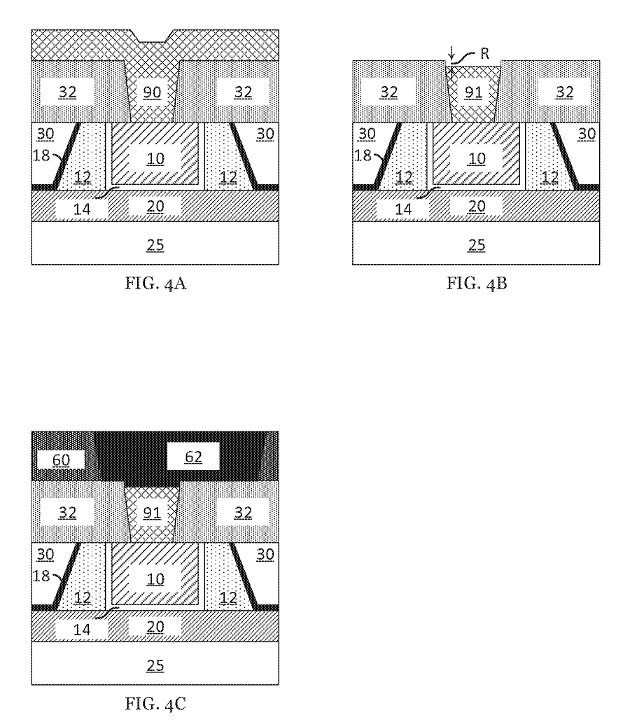

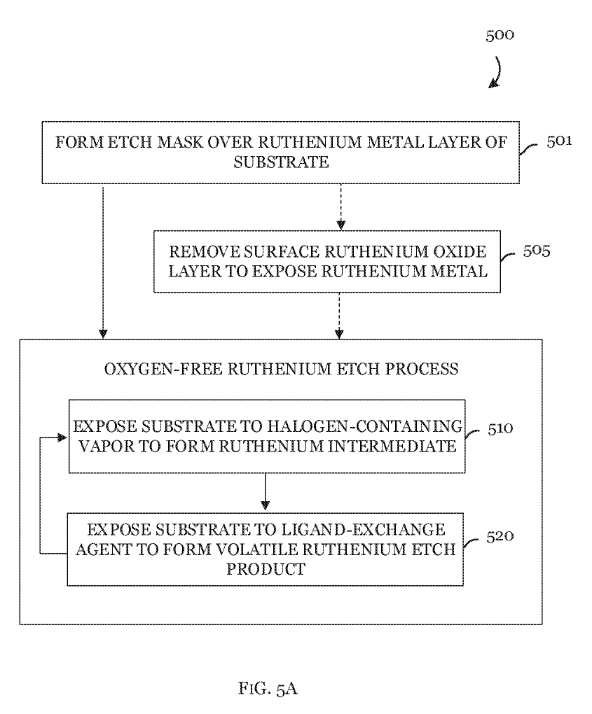

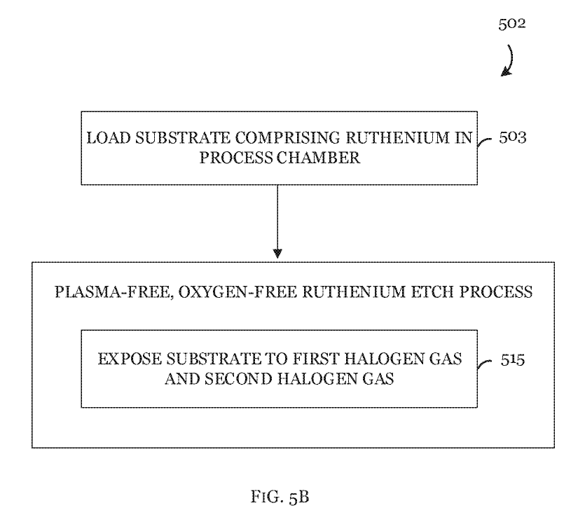

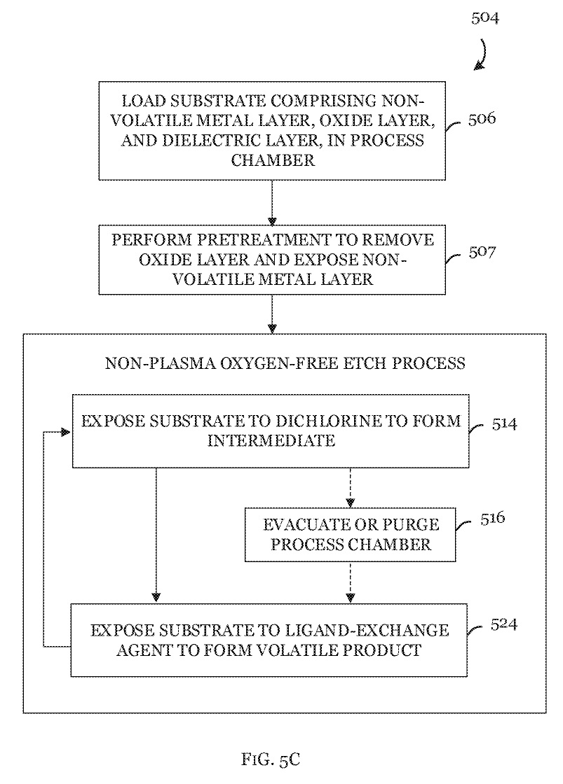

In the following, a multi-step oxygen-free etching process is first described referring to FIGS. 1A-1D in accordance with various embodiments. Alternate embodiments for a continuous process is then described referring to FIG. 2. Two example BEOL processes for Ru patterning utilizing the oxygen-free etching process are illustrated in FIGS. 3A-3D and 4A-4C. Example process flow diagrams are illustrated in FIG. 5A-5C. All figures in this disclosure are drawn for illustration purpose only and not to scale, including the aspect ratios of features.

FIGS. 1A-1D illustrate cross-sectional views of an example substrate 100 during a fabrication process comprising an oxygen-free etching process in accordance with various embodiments.

FIG. 1A illustrates the incoming substrate 100 comprising a Ru metal layer 110 and a surface Ru oxide layer 120.

In various embodiments, the substrate 100 may be a part of, or including, a semiconductor device, and may have undergone a number of steps of processing following, for example, a conventional process. The substrate 100 accordingly may comprise layers of semiconductors useful in various microelectronics. For example, the semiconductor structure may comprise the substrate 100 in which various device regions are formed.

In one or more embodiments, the substrate 100 may be a silicon wafer, or a silicon-on-insulator (SOI) wafer. In certain embodiments, the substrate 100 may comprise silicon germanium, silicon carbide, gallium arsenide, gallium nitride, and other compound semiconductors. In other embodiments, the substrate 100 comprises heterogeneous layers such as silicon germanium on silicon, gallium nitride on silicon, silicon carbon on silicon, as well layers of silicon on a silicon or SOI substrate. In various embodiments, the substrate 100 is patterned or embedded in other components of the semiconductor device.

The Ru metal may be deposited over the substrate to form the Ru metal layer 110 using suitable deposition techniques such as vapor deposition including chemical vapor deposition (CVD), physical vapor deposition (PVD), sputtering, and other processes. In certain embodiments, as illustrated in FIG. 1A, there may be the surface Ru oxide layer 120 on the Ru metal layer 110, which may be a native oxide layer that forms on a metallic surface of the Ru metal at ambient conditions if the substrate 100 is exposed to any oxygen-containing environment (e.g., air). In other embodiments, the deposition of the Ru metal layer 110 and subsequent process steps may be performed without any exposure to oxygen (e.g., by performing all the steps in a same vacuum chamber), and the substrate 100 may not comprise the surface Ru oxide layer 120.

In FIG. 1A, the substrate 100 may further comprise a patterned hard mask layer 115. The patterned hard mask layer 115 may comprise silicon oxide in one embodiment. In various embodiments, the patterned hard mask layer 115 may comprise silicon nitride, silicon carbonitride (SiCN), or silicon oxycarbide (SiOC). In alternate embodiments, the patterned hard mask layer 115 may comprise titanium nitride. In one or more embodiments, the patterned hard mask layer 115 may comprise other suitable organic materials such as spin-on carbon hard mask (SOH) materials. Further, the patterned hard mask layer 115 may be a stacked hard mask comprising, for example, two or more layers using two different materials. In some of such embodiments, a first hard mask may comprise a metal-based layer such as titanium nitride, titanium, tantalum nitride, tantalum, tungsten based compounds, or aluminum based compounds, and a second hard mask material may comprise a dielectric layer such as silicon oxide, silicon nitride, SiCN, SiOC, silicon oxynitride, or silicon carbide. The hard mask may be deposited using suitable deposition techniques such as vapor deposition including chemical vapor deposition (CVD), physical vapor deposition (PVD), as well as other plasma processes such as plasma enhanced CVD (PECVD), sputtering, and other processes including wet processes. The hard mask layer 130 may have a thickness of about 5 nm to about 50 nm in various embodiments. In one or more embodiments, an additional layer such as silicon-containing anti-reflective coating films (SiARC) or other ARC films may be formed over the patterned hard mask layer 130. In various embodiments, after a layer of the hard mask is deposited over the substrate 100, patterning of the hard mask may be performed by a conventional photolithographic process using a photoresist followed by a pattern transfer etch.

Prior to performing an oxygen-free etching process, a pretreatment may be performed to remove the surface Ru oxide layer 120 to expose the surface of the Ru metal layer 110. In various embodiments, the pretreatment may be a plasma process or a radical process, for example, comprising exposing the substrate 100 to radical species generated from a halogen-containing pretreatment gas. In one embodiment, the pretreatment gas may comprise nitrogen trifluoride (NF₃), chlorine (Cl₂), chlorine trifluoride (ClF₃), carbon tetrafluoride (CF₄), sulfur hexafluoride (SF₆), boron trichloride (BCl₃), trifluoro methane (CHF₃).

FIG. 1B illustrates a cross sectional view of the substrate 100 after removing the surface Ru oxide layer 120.

After removing the surface Ru oxide layer 120, the Ru metal layer 110 is exposed on surface, which may be subject to an oxygen-free etching process as described below. In certain embodiments, the incoming substrate 100 may not contain a surface Ru oxide layer and thereby a pretreatment to remove the surface Ru oxide layer may not be required, which nevertheless does not preclude any other pretreatment steps for the substrate 100 prior to the oxygen-free etching process.

FIG. 1C illustrates the cross sectional view of the substrate 100 after exposing the substrate 100 to a first halogen-containing vapor 130.

The first step of the oxygen-free etching process is to form a Ru intermediate 140. The Ru intermediate 140 may be formed over the substrate 100 by exposing the substrate 100 to the first halogen-containing vapor 130. In various embodiments, the reaction between the first halogen-containing vapor 130 and the Ru metal may be self-limiting and only occurs at surface or near surface. Accordingly, as illustrated in FIG. 1C, the Ru intermediate 140 may be formed as a thin film as a result of the reaction of a surface portion of the Ru metal layer 110. In one embodiment, such a thin film of the Ru intermediate 140 may have a thickness between a few nm and tens of nm, but in other embodiments, the thin film may have any thickness. This reaction to form the Ru intermediate 140 may be a halogenation of Ru, for example, chlorination. In certain embodiments, the first halogen-containing vapor 130 may comprise a chlorine (Cl₂), chlorine trifluoride (ClF₃), carbon tetrafluoride (CF₄), sulfur hexafluoride (SF₆), boron trichloride (BCl₃), trifluoro methane (CHF₃). In various embodiments, the Ru intermediate 140 may be more volatile than the Ru metal, but its volatility may still be not high enough to enable any substantial removal of Ru species under process conditions such as in the absence of plasma. Therefore, a subsequent second step of further conversion may be necessary, which will be described below referring to FIG. 1D.

The “oxygen-free” feature of the methods described in this disclosure means that no dioxygen (O₂), ozone (O₃), or an oxygen-containing gas that generates oxygen radicals may be used during the etching process, ensuring the etching is not driven by oxygen species. It should be noted, however, as described above, oxygen may be found in various layers of the substrate 100, e.g., the surface Ru oxide layer 120 of the substrate 100 being processed by the “oxygen-free” etching process. Such oxygen may be assumed to have little to no impact as an etchant during the etching process. The inventors of this disclosure identified that conventional Ru etching processes are often plasma processes that uses oxygen (e.g., O₂, O₃, etc.), where the oxygen species may be the primary etchant. Alternately, conventional processes may use a mixture of oxygen and chlorine. In both cases, the oxygen-containing etchant species tend to be detrimental to other materials such as low-k dielectric. Accordingly, the methods herein, referred to as “oxygen-free” in this disclosure, advantageously avoid using any oxygen-containing process gas.

In various embodiments, the exposure to the first halogen-containing vapor 130 may be performed in the absence of plasma, and accordingly the oxygen-free etching process may not be a plasma process.

In certain embodiments, the halogenation of Ru may involve radical species such as chlorine radicals (Cl•). In one embodiment, a power of 500 W to 1000 1000 may be applied to the processing chamber to facilitate the generation of radical species without forming a plasma. During this first exposure step, the temperature of the substrate 100 may be kept at 100° C. or above in one embodiment, but in another embodiment may be between 120° C. and 300° C. Accordingly, the substrate 100 may be heated by a lamp or a heating coil, e.g., placed in the substrate holder prior to processing. In one or more embodiments, the pressure in the processing chamber may be between 1 Torr and 20 Torr.

FIG. 1D illustrates the cross sectional view of the substrate 100 after exposing the substrate 100 to a ligand-exchange agent 150 to etch the Ru metal from the substrate 100.

The second step of the oxygen-free etching process comprises etching the Ru metal from the surface of the substrate 100 by further converting the Ru intermediate 140 to Ru etch product 160. In various embodiments, this conversion to the Ru etch product 160 may be realized by a ligand-exchange reaction, where one or more ligands of the ligand-exchange agent 150 replace those of the Ru intermediate 140 (e.g., chlorine) to further increase the volatility. As a result, the thin film of the Ru intermediate 140 formed during the first step (FIG. 1C) may be removed and a new surface of the Ru metal layer 110 may be exposed. In various embodiments, the ligand-exchange agent 150 may comprise acetylacetone (ACAC), hexafluoroacetylacetone (HFAC), acetic acid, amides, ethylene, or acetylene.

In various embodiments, similar to the first exposure step, the second exposure step may be performed in the absence of plasma. The non-plasma feature of both the first and second exposure steps allows the oxygen-free etching process to proceed less aggressively, which may further improve the etch selectivity to materials such as low-k dielectric. Additionally, because the etching process may not require plasma, a processing system simpler than a conventional plasma processing system may advantageously be utilized to perform the oxygen-free etching process in various embodiments.

This second exposure step may be performed in a dry process. In various embodiments, the substrate 100 may be exposed to a vapor of the ligand-exchange agent 150, and the Ru etch product 160 may be etched to a gas phase. Accordingly, both the first and second exposure steps may be performed in a common processing chamber. In various embodiments, the exposure to the ligand-exchange agent 150 may be performed in the absence of plasma. Further, similar to the first exposure step, no O₂, O₃, or an oxygen-containing gas that generates oxygen radicals may be used to perform a dry process of the second exposure step. The etching process is thus still an “oxygen-free” process. During this second exposure step, the temperature of the substrate 100 may be kept at 100° C. or above in one embodiment, but in another embodiment may be between 120° C. and 300° C. In one or more embodiments, the pressure in the processing chamber may be between 1 Torr and 20 Torr.

As described above, the oxygen-free etching process may proceed step wise, which may be regarded as an atomic layer etching (ALE) or pseudo-ALE process, where the removal of material proceeds layer by layer. Therefore, the oxygen-free etching process may comprise a cyclic process where the steps described above (e.g., FIGS. 1B-1D) are repeated for any number of times to achieve a desired level of etching, for example, until the entirety of the Ru metal layer 110 is removed.

In certain embodiments, when the method is performed in a cyclic fashion, one or more evacuating or purging steps may be inserted between any exposure steps. An inert gas such as dinitrogen (N₂) or a noble gas may be used in a purge step to purge the processing chamber prior to a subsequent exposure step. Ensuring there is no residual reactants in the processing chamber at each step may advantageously prevent any possible gas phase reactions and undesired material depositions.

In alternate embodiments, the exposure steps may be overlapped in time. For example, the exposure to the ligand-exchange agent 150 may be started while the first halogen-containing vapor 130 may be present in the processing chamber. In further embodiments, they may be completely merged into a single step to enable a continuous process of the oxygen-free etching process.

FIG. 2 illustrates a cross sectional view of an example substrate 100 during a continuous oxygen-free etching process in accordance with alternate embodiments.

In contrast to the prior embodiments of a multi-step process, a single step of exposure may be performed. In FIG. 2, the substrate 100 comprises a surface of a Ru metal layer 110, similar to FIG. 1B, and may be exposed, in the absence of oxygen, to a gas mixture comprising a first halogen-containing vapor 130 and a second halogen-containing vapor 155. This single exposure can enable the etching of Ru and form Ru etch product 160. In various embodiments, the first halogen-containing vapor 130 comprise a first halogen to enable a certain degree of halogenation of the Ru metal on surface, and the second halogen-containing vapor comprises a second halogen that can replace some of the first halogen atoms of the halogenated Ru. For example, the first halogen may be chlorine and the second halogen may be fluorine. In general, the volatility of a Ru fluoride can be higher than that of a Ru chloride counterpart. Accordingly, although a process may be continuous, the methods in various embodiments may rely on step-wise reactions on surface to from a volatile etch product comprising the second halogen. In certain embodiments, the first halogen-containing vapor 130 may comprise chlorine (Cl₂), and the second halogen-containing vapor 155 may comprise carbon tetrafluoride (CF₄), sulfur tetrafluoride (SF₄), sulfur hexafluoride (SF₆), nitrogen trifluoride (NF₃), chlorine trifluoride (ClF₃), or trifluoro methane (CHF₃). The inventors of this application demonstrated, in one example, that the etching of Ru metal may proceed in the absence of oxygen and plasma using a gas mixture comprising chlorine and fluorine, at a pressure between 1 Torr and 20 Torr and at a temperature between 120° C. and 300° C. Although not wishing to be limited by any theory, the use of two halogen sources may enable step-wise halogenations of Ru, for example, a partial chlorination followed by a partial fluorination. Accordingly, the Ru etch product 160 may comprise a metal halide with a varying degree of halogenation with either chlorine or fluorine. In various embodiments, the continuous oxygen-free etching process may be performed in the absence of plasma. Such a continuous, plasma-free embodiment for the oxygen-free etching process may advantageously simplify the process recipe and thereby process efficiency.

FIGS. 3A-3D illustrate cross sectional views of another example substrate 25 comprising direct-etch interconnect lines disposed between a damascene contact level and a dual-damascene interconnect level at various intermediate stages of fabrication including an oxygen-free etching process in accordance with other embodiments.

In FIG. 3A, a Ru film 40 having a thickness, for example, of about 40 nm to about 80 nm may be deposited using a suitable technique (e.g., CVD, ALD, magnetron sputtering, or the like) over two vertically adjacent interlayer dielectric (ILD) layers, referred to as ILD1 30 and ILD2 32, comprising insulators such as SiO₂ or a silicon oxide based low-k dielectric (e.g., porous oxides, fluorosilicate glass (FSG), and organosilicate glass (OSG)). Optionally, the bottom layer of the ILD2 32 may be an etch-stop layer (ESL) comprising a dielectric such as Si₃N₄, SiOₓN_{y}, SiC, or SiCN (not shown). In some applications, an optional conductive ESL 42 comprising, for example, TiN or TaN may be formed over the ILD2 32 before the Ru film 40 is deposited. A contact 35 inlaid in ILD2 32 is shown connected to a gate structure of a FinFET comprising a metal gate 10 (e.g., a multilayer metal stack comprising Ta, TaN, TiN, W, and the like, or a combination thereof) and a high-k gate dielectric 14 (e.g., HfO₂, or Al₂O₃) inlaid within a recess formed earlier between a pair of source/drain spacers 12 (e.g., SiOₓN_{y} spacers). A source/drain contact etch-stop layer (CESL) 18 (e.g., a Si₃N₄ layer) is shown lining the bottom surface of the ILD1 30. In FIG. 3A, the metal gate 10 and a gate dielectric 14 are a portion of the metal gate structure extending over a shallow trench isolation (STI) region 20 in recesses between semiconductor fins formed earlier, for example, by etching a semiconductor substrate 25 (e.g., a bulk crystalline Si wafer). The semiconductor fins are not visible, being located along planes parallel to the plane of the cross-sectional views in FIG. 3A. A patterned masking layer 44 may be formed over the Ru film 40. The patterned masking layer 44 may comprise dielectrics such as SiO₂, and Si₃N₄, or conductive materials such as TaN, Ti, and TiN, or a combination thereof that can provide etch selectivity with respect to Ru. The thickness of the patterned masking layer 44 used may vary in accordance with the etch selectivity with respect to Ru and the target thickness of Ru to be removed.

FIG. 3B illustrates a cross sectional view of the substrate 25 after the oxygen-free etching process, and FIG. 3C illustrates a cross sectional view of the substrate 25 after removing an etch stop layer.

In FIG. 3B, the Ru film 40 is etched by the oxygen-free etching process in accordance with the embodiments described above, in a step-wise or continuous fashion. Ru is removed from a portion of the top surface of the Ru exposed by the openings in the patterned masking layer 44. The exposed Ru may be etched vertically till the underlying layer, for example, the conductive ESL 42 is exposed, thereby forming a patterned Ru film 41. The exposed portion of the conductive ESL 42 and the patterned masking layer 44 may be removed during subsequent processing steps, as illustrated in FIG. 3C. The remaining patterned Ru film 41 and conductive ESL 42 form the conductive lines of the respective interconnect level.

FIG. 3D illustrates a cross sectional view of the substrate 25 after forming an intermetal dielectric (IMD) layer.

FIG. 3D illustrates the patterned Ru film 41 covered by an intermetal dielectric (IMD) layer 50, and the next interconnect level formed over the Ru level using, for example, a conventional Cu dual-damascene flow. The materials used to form IMD 50 may comprise insulators such as SiO₂ or a silicon oxide based low-k dielectric (e.g., porous oxides, fluorosilicate glass (FSG), and orthosilicate glass (OSG)), similar to ILD2 32. The copper via 52 in FIG. 3D connects the copper line 56 to a portion of the patterned Ru film 41 disposed directly below the copper line 56. As known by a person skilled in the art, the dual-damascene flow comprises patterning openings (e.g., holes for copper vias 52 and trenches for copper lines 56) in the IMD 50 using a via-first or a trench-first patterning sequence, depositing a conformal barrier metal (e.g., TiN or TaN) liner, filling the openings with metal (e.g., using Cu electroplating), and removing all excess conductive material from the top surface of IMD 50 using a planarization process such as chemical mechanical planarization (CMP), thereby forming the copper vias 52 and copper lines 56 inlaid in the IMD 50.

One advantage of forming the Ru interconnect level using a dry etch process as illustrated in FIG. 3A-3D, is that such a process avoids using a Ru metal CMP step which is difficult and expensive to perform.

FIGS. 4A-4C illustrate cross sectional views of yet another example substrate 25 comprising a direct-etch back contact connecting a conductive gate to a metal line at various intermediate stages of fabrication including an oxygen-free etching process in accordance with yet other embodiments. Some structures are same as those illustrated in FIGS. 3A-3D, and thus will not be repeated in detail.

FIG. 4A illustrates a Ru layer 90 formed over ILD2 32 filling a contact opening extending through the ILD2 32 and making physical contact with a portion of the top surface of the metal gate 10. In various embodiments, as an example, the diameter of the contact opening may be about 15 nm to about 40 nm and the thickness of the ILD2 32 (also the height of the contact opening prior to Ru deposition) may be about 20 nm to about 80 nm. The ratio of the thickness of the excess metal over the flat top surface of the ILD2 32 to the thickness of the Ru in contact with the top surface of the metal gate 10 may be about 1:2 to about 1:5.

FIG. 4B illustrates a cross sectional view of the substrate 25 after the oxygen-free etching process.

In FIG. 4B, the excess Ru metal over the top surface of the ILD2 32 is removed using the oxygen-free etching process as described above. The oxygen-free etching process is applied in an etch back step, which may selectively remove the excess Ru to form a top surface comprising two surfaces. A first surface of the insulating ILD2 layer 32 and a second surface of the conductive Ru plug 91 inlaid in the ILD2 32, as illustrated in FIG. 4B, are thus formed. The conductive Ru plugs 91 are formed preferably with minimal recess (R) to preserve the integrity and performance of the contact structure while, simultaneously, minimizing the defect density of Ru residue over the insulating top surface of the ILD2 32. In some embodiments, a small recess R of about 0.5 nm to 10 nm may be formed.

FIG. 4C illustrates a cross sectional view of the substrate 25 after forming an interconnect level.

FIG. 4C illustrates an interconnect level (e.g., a Cu interconnect level) formed vertically adjacent above the contact level. In the example in FIG. 4C, a metal line 62 inlaid in IMD 60 is shown directly above the metal gate 10, and the conductive Ru plug 91 forms a physical and electrical connection between the two. The dielectrics used for IMD 60 may be same as those used for ILD2 32. In some other application the upper interconnect element may be a via instead of the metal line 62.

In the above example of FIGS. 4A-4C, the oxygen-free etching process is utilized as an etch back in the formation of Ru contacts and vias. In conventional multilevel interconnect systems, tungsten and copper are used as the fill-material to fill openings for contacts and vias, respectively. As mentioned earlier, the advantage of using Ru is that its product of bulk resistivity times the mean free path is lower than that in either copper or in tungsten. At room temperature, the product in Ru is about 70 % of that in copper and about 60 % of that in tungsten. Furthermore, relatively resistive liners (e.g., TiN thin films), which are generally used as an adhesive layer for tungsten and as a diffusion barrier for copper, may not need to be used in contacts/vias formed using Ru.

It is understood by a person skilled in the art that the flows described in FIGS. 2 and 3 may be modified and combined to form interconnect elements comprising integrated Ru structures for both contacts and vertically adjacent lines. For example, a patterned hard mask, similar to the patterned masking layer 44 may be used to form an integrated Ru contact and line structure.

FIGS. 5A-5C illustrate process flow charts of methods of oxygen-free etching in accordance with various embodiments. The process flow can be followed with the figures(FIGS. 1A-1D and 2) discussed above and hence will not be described again.

In FIG. 5A, a process flow 500 may start with forming a patterned etch mask over a Ru metal layer of a substrate (block 501, FIG. 1A), where the patterned etch mask exposes a portion of the Ru metal layer and covers another portion of the Ru metal layer. In certain embodiments, when a surface Ru oxide layer is present over the substrate, an optional pretreatment may be performed to remove the surface Ru oxide layer (block 505, FIG. 1B). The Ru etch process may then be started by exposing the substrate to a halogen-containing vapor, such as chlorine (Cl₂) in a processing chamber in the absence of oxygen to form a Ru intermediate on surface (block 510, FIG. 1C). After this first exposure step, a second exposure step may be performed by exposing the substrate to a ligand-exchange agent that reacts with the Ru intermediate to form a volatile Ru etch product (block 520, FIG. 1D). In certain embodiments, these two exposure steps (blocks 510 and 520) may be repeated as a part of a cyclic etch process. For the cyclic etch process, an optional evacuating or purging step may be inserted between any exposure steps. In alternate embodiments, the exposure steps may be overlapped in time.

In FIG. 5B, a process flow 502 starts with loading a substrate comprising Ru metal in a processing chamber (block 503), and the substrate may be exposed, in the absence of oxygen and plasma, to a process gas mixture comprising a first halogen-containing gas such as Cl₂ and a second halogen-containing gas such as CF₄, SF₄, SF₆, NF₃, ClF₃, and CHF₃ (block 515, FIG. 2). The etching of Ru may proceed continuously in this single-step process.

In FIG. 5C, a process flow 504 starts with loading a substrate in a processing chamber (block 506), where the substrate comprises a non-volatile metal layer, an oxide layer, and a dielectric layer. Next, a pretreatment may be performed by exposing the substrate to a treatment gas to remove the oxide layer and expose the non-volatile metal layer (block 507). Once the non-volatile metal layer is exposed on surface, a non-plasma etch process may be performed selectivity to the dielectric layer. In the non-plasma etch process, the substrate may be first exposed to Cl₂ in the processing chamber in the absence of oxygen and plasma (block 514). The reaction of Cl₂ and the non-volatile metal may form an intermediate. After the first exposure step, an optional evacuating or purging step may be performed in certain embodiments (block 516). A second exposure step may then be performed by exposing the substrate to a ligand-exchange agent in the processing chamber to form volatile products (block524).

Embodiments may use a gas comprising Cl₂ in the first step of the oxygen-free etching process. When the first exposure step was performed with a pure Cl₂ gas at a temperature between 120° C. and 300° C. , the inventors of this application have identified that the chlorination of Ru proceeded in the absence of oxygen and plasma. The substrate after the first exposure step was characterized with scanning electron microscopy (SEM) to confirm the surface thin film formation, secondary ion mass spectrometry (SIMS) was used to measure the depth of the fluorine treatment and the reduction of Ru thickness after the etch, and X-ray photoelectron spectroscopy (XPS) was used to measure the degree of chlorination of Ru, and the presence of Ru and Cl in the thin film formed on surface was confirmed.

Example embodiments of the invention are summarized here. Other embodiments can also be understood from the entirety of the specification as well as the claims filed herein.

Example 1. A method of processing a substrate that includes: forming an etch mask over a ruthenium (Ru) metal layer of a substrate, the etch mask exposing a first portion of the Ru metal layer and covering a second portion of the Ru metal layer; and converting the first portion of the Ru metal layer into a volatile Ru etch product in a processing chamber, the converting including exposing the Ru metal layer of the substrate to a halogen-containing vapor, and to a ligand-exchange agent to form the volatile Ru etch product, where the converting is an oxygen-free process.

Example 2. The method of example 1, the oxygen-free etch process further including repeating the exposure steps.

Example 3. The method of one of examples 1 or 2, further including: flowing the halogen-containing vapor to the processing chamber; and generating radicals of halogen from the halogen-containing vapor, where the radicals of halogen cause halogenation of the Ru metal.

Example 4. The method of one of examples 1 to 3, where the halogen-containing vapor includes chlorine (Cl₂).

Example 5. The method of one of examples 1 to 4, where the exposing to the ligand-exchange agent is a dry process using a vapor of the ligand-exchange agent.

Example 6. The method of one of examples 1 to 5, where the ligand-exchange agent includes acetylacetone (ACAC) or hexafluoroacetylacetone (HFAC).

Example 7. The method of one of examples 1 to 6, where the exposing to the ligand-exchange agent includes acetic acid, amides, ethylene, or acetylene.

Example 8. The method of one of examples 1 to 7, where the surface of the substrate includes a Ru oxide layer, the method further including, prior to the converting, removing the Ru oxide layer to expose the surface portion of the Ru metal.

Example 9. The method of one of examples 1 to 8, where the removing is performed by exposing the Ru oxide layer to a vapor including nitrogen trifluoride (NF₃).

Example 10. A method of processing a substrate that includes; performing a plasma-free and oxygen-free etch process, the performing including exposing the substrate including ruthenium (Ru) metal to a process gas mixture, the process gas mixture including a first halogen-containing gas and a second halogen-containing gas, the second halogen-containing gas including a halogen different from that of the first halogen-containing gas.

Example 11. The method of example 10, where the first halogen-containing gas includes chlorine and the second halogen-containing gas includes fluorine.

Example 12. The method of one of examples 10 or 11, where the first halogen-containing gas includes chlorine (Cl₂).

Example 13. The method of one of examples 10 to 12, where the second halogen-containing gas includes carbon tetrafluoride (CF₄), sulfur tetrafluoride (SF₄), sulfur hexafluoride (SF₆), nitrogen trifluoride (NF₃), chlorine trifluoride (ClF₃), or trifluoro methane (CHF₃).

Example 14. The method of one of examples 10 to 13, further including maintaining the temperature of the substrate between 120°C and 300°C during the performing.

Example 15. A method of processing a substrate that includes; loading the substrate in a processing chamber, the substrate including a non-volatile metal layer, an oxide layer, and a dielectric layer, the oxide layer including an oxide of the non-volatile metal, a surface of the substrate including the oxide layer and the dielectric layer; performing a pretreatment by exposing the substrate to a treatment gas to remove the oxide layer and expose the non-volatile metal layer; performing a non-plasma oxygen-free etch process selective to the dielectric layer by: exposing the substrate to chlorine (Cl₂) in the processing chamber, the Cl₂ reacting with the non-volatile metal to form an intermediate; and exposing the substrate to a ligand-exchange agent in the processing chamber, the ligand-exchange agent reacting with the intermediate to form volatile products, removing the non-volatile metal from the surface of the substrate.

Example 16. The method of example 15, where the exposing to the Cl₂ and the exposing to the ligand-exchange agent are overlapped.

Example 17. The method of one of examples 15 or 16, further including, prior to performing the non-plasma oxygen-free etch process, evacuating or purging the processing chamber to remove oxygen from the processing chamber.

Example 18. The method of one of examples 15 to 17, the non-plasma oxygen-free etch process further including an evacuating or purging step between the exposure steps.

Example 19. The method of one of examples 15 to 18, the non-volatile metal includes ruthenium (Ru), osmium (Os), or hafnium (Hf).

Example 20. The method of one of examples 15 to 19, where the ligand-exchange agent includes acetylacetone (ACAC) or hexafluoroacetylacetone (HFAC).

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
performing a plasma-free and oxygen-free etch process, the performing comprising:
exposing the substrate comprising ruthenium (Ru) metal to a process gas mixture, the process gas mixture comprising a first halogen-containing gas and a second halogen-containing gas, the second halogen-containing gas comprising a halogen different from that of the first halogen-containing gas.

2. The method of claim 1, wherein the first halogen-containing gas comprises chlorine and the second halogen-containing gas comprises fluorine.

3. The method of claim 2, wherein the first halogen-containing gas comprises chlorine (Cl₂).

4. The method of claim 2, wherein the second halogen-containing gas comprises carbon tetrafluoride (CF₄), sulfur tetrafluoride (SF₄), sulfur hexafluoride (SF₆), nitrogen trifluoride (NF₃), chlorine trifluoride (ClF₃), or trifluoro methane (CHF₃).

5. The method of claim 1, further comprising maintaining a temperature of the substrate between 120°C and 300°C during the performing.

6. A method of processing a substrate, the method comprising:
loading the substrate in a processing chamber, the substrate comprising a non-volatile metal layer, an oxide layer, and a dielectric layer, the oxide layer comprising an oxide of the non-volatile metal, a surface of the substrate comprising the oxide layer and the dielectric layer;
performing a pretreatment by exposing the substrate to a treatment gas to remove the oxide layer and expose the non-volatile metal layer; and
performing a non-plasma oxygen-free etch process selective to the dielectric layer by:
exposing the substrate to chlorine (Cl₂) in the processing chamber, the Cl₂ reacting with the non-volatile metal to form an intermediate; and
exposing the substrate to a ligand-exchange agent in the processing chamber, the ligand-exchange agent reacting with the intermediate to form volatile products, removing the non-volatile metal from the surface of the substrate.

7. The method of claim 6, wherein the exposing to the Cl₂ and the exposing to the ligand-exchange agent are overlapped.

8. The method of claim 6, further comprising, prior to performing the non-plasma oxygen-free etch process, evacuating or purging the processing chamber to remove oxygen from the processing chamber.

9. The method of claim 6, wherein the non-plasma oxygen-free etch process further comprises an evacuating or purging step between the exposure steps.

10. The method of claim 6, wherein the non-volatile metal comprises ruthenium (Ru), osmium (Os), or hafnium (Hf).

11. The method of claim 6, wherein the ligand-exchange agent comprises acetylacetone (ACAC) or hexafluoroacetylacetone (HFAC).

12. A method of processing a substrate, the method comprising:
loading the substrate in a processing chamber, the substrate comprising a ruthenium (Ru) metal layer, a Ru oxide layer disposed on the Ru metal layer, and a dielectric layer, a surface of the substrate comprising the Ru oxide layer and the dielectric layer;
performing a pretreatment process comprising exposing the substrate to a halogen-containing pretreatment gas to remove the Ru oxide layer and expose the Ru metal layer at the surface of the substrate; and
after performing the pretreatment process, performing a non-plasma oxygen-free etch process selective to the dielectric layer, performing the non-plasma oxygen-free etch process comprising:
exposing the substrate to chlorine (Cl₂) in the processing chamber, the Cl₂ reacting with the Ru metal layer to form a Ru intermediate at the surface of the substrate; and
exposing the substrate to a ligand-exchange agent in the processing chamber, the ligand-exchange agent reacting with the Ru intermediate to form a volatile Ru etch product, thereby removing Ru from the surface of the substrate.

13. The method of claim 12, wherein the halogen-containing pretreatment gas comprises nitrogen trifluoride (NF₃), chlorine (Cl₂), chlorine trifluoride (ClF₃), carbon tetrafluoride (CF₄), sulfur hexafluoride (SF₆), boron trichloride (BCl₃), or trifluoro methane (CHF₃).

14. The method of claim 12, wherein the non-plasma oxygen-free etch process is performed at a pressure between 1 Torr and 20 Torr.

15. The method of claim 12, wherein the Ru intermediate is formed as a thin film having a thickness between a few nanometers and tens of nanometers.

16. The method of claim 12, wherein the ligand-exchange agent comprises acetylacetone (ACAC), hexafluoroacetylacetone (HFAC), acetic acid, an amide, ethylene, or acetylene.

17. The method of claim 12, wherein the pretreatment process and the non-plasma oxygen-free etch process are performed in the processing chamber.

18. The method of claim 12, wherein the dielectric layer comprises a low-k dielectric material.

19. The method of claim 12, further comprising, after performing the non-plasma oxygen-free etch process, measuring a reduction of a thickness of the Ru metal layer using secondary ion mass spectrometry (SIMS).

20. The method of claim 12, further comprising characterizing the surface of the substrate using X-ray photoelectron spectroscopy (XPS) to determine a degree of chlorination of the Ru intermediate.
